(19) United States
(12) Patent Application Publication
(10) Pub. No.: US 2026/0239615 A1
(43) Pub. Date: Aug. 13, 2026

(54) METHOD FOR FORMING SEMICONDUCTOR STRUCTURE

(71) Applicant: Winbond Electronics Corp., Taichung City (TW)

(72) Inventor: I-Kuo CHEN, Miaoli County (TW)

(73) Assignee: Winbond Electronics Corp., Taichung City (TW)

(21) Appl. No.: 19/418,231

(22) Filed: Dec. 12, 2025

(30) Foreign Application Priority Data
Feb. 7, 2025 (TW) 114104468

(51) Int. Cl. H10B 41/30

(52) U.S. Cl. CPC H10B 41/30

(57) ABSTRACT

A method for forming a semiconductor structure including providing a substrate, forming a first gate layer and a mask layer on the substrate, and etching the substrate to form trenches. The method includes forming a first dielectric layer with a first air gap in the trench, etching the first dielectric layer to expose a top of the first air gap, and performing an ion implantation process on the first dielectric layer to form an etch-stop layer at the upper portion of the first dielectric layer. The method further includes etching the first air gap to form a second air gap, forming a second dielectric layer in the trench, etching back the substrate to expose the first gate layer with the second dielectric layer remaining at the top of the first air gap, and forming a gate dielectric layer and a second gate layer on the substrate.

### CROSS REFERENCE TO RELATED APPLICATIONS

This application claims priority of Taiwan patent application No. 114104468, filed February 7, 2025, the entirety of which is incorporated by reference herein.

### TECHNICAL FIELD

The present disclosure relates to a method for forming a semiconductor structure, and, in particular, it relates to a method for forming a flash memory structure.

### BACKGROUND

Flash memory is a type of non-volatile memory characterized by high capacity, fast read/write speeds, low power consumption, and low cost. Due to its non-volatile nature, data stored in flash memory may be retained even after it is powered-off. As a result, flash memory is widely used in various applications.

In order to increase the component density within flash memory devices and improve overall performance, current manufacturing technologies for flash memory continue to advance toward device scaling. For example, as device scaling progresses, improved isolation between bit line structures is required to meet performance demands, such as reducing potential leakage current. Therefore, there remains a need to improve the methods of manufacturing flash memory devices to maintain the yield.

### BRIEF SUMMARY

An embodiment of the present disclosure provides a method for forming a semiconductor structure, including providing a substrate and sequentially forming a first gate layer and a mask layer over the substrate. The method further includes etching the substrate to form a plurality of active regions. The active regions are isolated from each other by a plurality of trenches, and the trenches penetrate through the mask layer and the first gate layer. The method further includes forming a first dielectric layer in the trenches. The first dielectric layer has a first air gap. The method further includes back-etching the first dielectric layer to expose a top portion of the first air gap, and performing an ion implantation process on the first dielectric layer to form an etch-stop layer at the upper portion of the first dielectric layer and surrounding the top portion of the first air gap. The method further includes removing a portion of the first dielectric layer exposed by the first air gap to form a second air gap, and forming a second dielectric layer on the first dielectric layer in the trenches. The method further includes back-etching the second dielectric layer and the mask layer to expose the top surface of the first gate layer. The second dielectric layer remains at the top portion of the first air gap. The method further includes conformally forming an inter-gate dielectric layer on the substrate and the first gate layer, and forming a second gate layer on the inter-gate dielectric layer.

### BRIEF DESCRIPTION OF THE DRAWINGS

FIGS. 1, 2, 3, 4, 5, 6, 7, 8 and 9, illustrate cross-sectional views of various process stages of forming the semiconductor structure according to the embodiments of the present disclosure.

### DETAILED DESCRIPTION

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

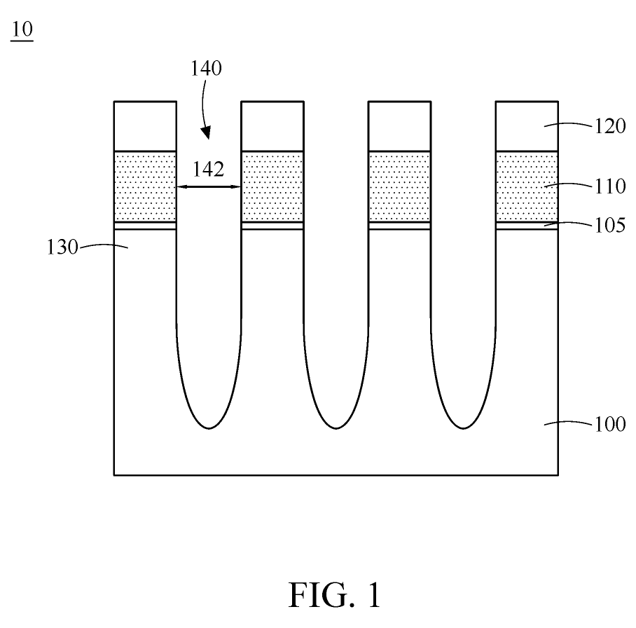

FIGS. 1 to 9 illustrate cross-sectional views of various process stages of forming the semiconductor structure 10 according to the embodiments of the present disclosure. Referring to FIG. 1, A substrate 100 is provided. In one embodiment, the substrate 100 may be an elemental semiconductor substrate, such as a silicon substrate or a germanium substrate; a compound semiconductor substrate, such as a silicon carbide, gallium arsenide, indium arsenide, or indium phosphide substrate; or an alloy semiconductor substrate, such as SiGe, SiGeC, GaAsP, or GaInP. In other embodiments, the substrate 100 may be a semiconductor-on-insulator (SOI) substrate. The semiconductor-on-insulator substrate may include a base substrate, a buried oxide layer disposed on the base substrate, and a semiconductor layer disposed on the buried oxide layer.

Still referring to FIG. 1, a gate layer 110 and a mask layer 120 are sequentially formed over the substrate 100. The gate layer 110 may later serve as the floating gate of the semiconductor structure 10. The mask layer 120 may be used to define the active regions and the trenches that are subsequently formed. In one embodiment, before forming the gate layer 110, a liner layer 105 may be formed on the substrate 100. The liner layer 105 may serve as a tunnel oxide layer of the semiconductor structure 10 (i.e., the tunnel oxide layer in a memory device). In one embodiment, the liner layer 105 may include an oxide, such as silicon oxide, and the liner layer 105 may be formed by a thermal oxidation process, a chemical vapor deposition (CVD) process, an atomic layer deposition (ALD) process, or a combination thereof. In one embodiment, the gate layer 110 may include doped polysilicon, undoped polysilicon, metal, polycide, or a combination thereof, and the gate layer 110 may be formed by a deposition process such as chemical vapor deposition, another suitable process, or a combination thereof. In one embodiment, the mask layer 120 may include a nitride, such as silicon nitride, and the mask layer 120 may be formed by a chemical vapor deposition process or another suitable process.

Still referring to FIG. 1, after the liner layer 105, the gate layer 110, and the mask layer 120 are formed, the substrate 100 is etched to form a plurality of active regions 130. The active regions 130 are isolated from each other by a plurality of trenches 140, and the trenches 140 penetrate through the mask layer 120 and the gate layer 110. In other words, the trenches 140 define the positions of the active regions 130. More specifically, the step of etching the substrate 100 may include first forming a patterned photoresist layer (not shown) to define the locations of the active regions 130, followed by an etching process to form the trenches 140, and subsequently removing the patterned photoresist layer to expose the top surface of the mask layer 120. In one embodiment, the trenches 140 may be formed by an anisotropic etching process (or directional etching process), such as a reactive ion etching (RIE) process, plasma etching, inductively coupled plasma (ICP) etching, or a combination thereof. In one embodiment, after the trenches 140 are formed, the patterned photoresist layer may be removed by an etching process, a stripping process, an ashing process, or a combination thereof.

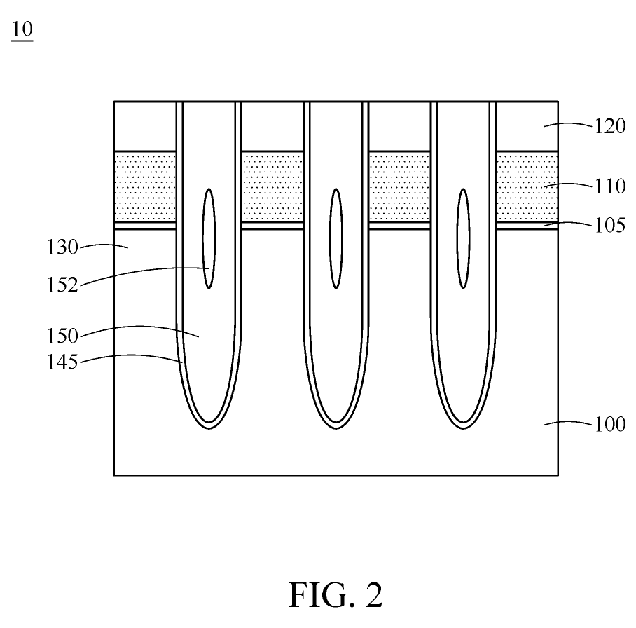

Next, referring to FIG. 2, a dielectric layer 150 is formed in the trenches 140, and the dielectric layer 150 includes a first air gap 152. In one embodiment, before forming the dielectric layer 150, a liner 145 may be formed to cover the trenches 140, and the liner 145 may assist in the formation of the dielectric layer 150. In one embodiment, after forming the dielectric layer 150, a chemical mechanical polishing (CMP) process may be performed on the dielectric layer 150 to expose the top surface of the mask layer 120. In one embodiment, the dielectric layer 150 may include an oxide or a nitride, such as an oxide formed from tetraethylorthosilicate (TEOS), and the dielectric layer 150 may be formed by a non-conformal chemical vapor deposition (CVD) process, a high aspect ratio process, or another suitable process. It should be noted that, in the embodiment of the present disclosure, because the dielectric layer 150 is formed by using a deposition process with a relatively high deposition rate and poor gap-filling capability, the opening of the trench 140 is sealed before it is completely filled, thereby forming the first air gap 152. The first air gap 152 is further expanded in a subsequent process to form a second air gap 200, thereby providing improved isolation between bit line structures.

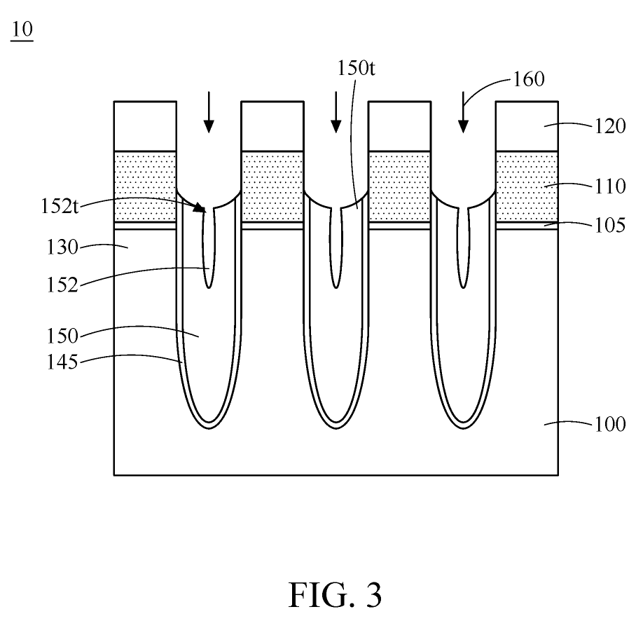

Referring to FIG. 3, after the dielectric layer 150 and the first air gap 152 are formed, a back-etching process 160 is performed on the dielectric layer 150 to expose a top portion 152t of the first air gap 152. In one embodiment, the back-etching process 160 etches the top surface of the dielectric layer 150 to a level that is lower than the top surface of the gate layer 110, and it etches the top surface of the dielectric layer 150 to a level that is higher than the top surface of the active regions 130. The depth of the dielectric layer 150 removed by the back-etching process 160 may depend on design requirements. In one embodiment, the back-etching process 160 may include an anisotropic etching process (or directional etching process), such as a reactive ion etching (RIE) process, plasma etching, inductively coupled plasma (ICP) etching, or a combination thereof.

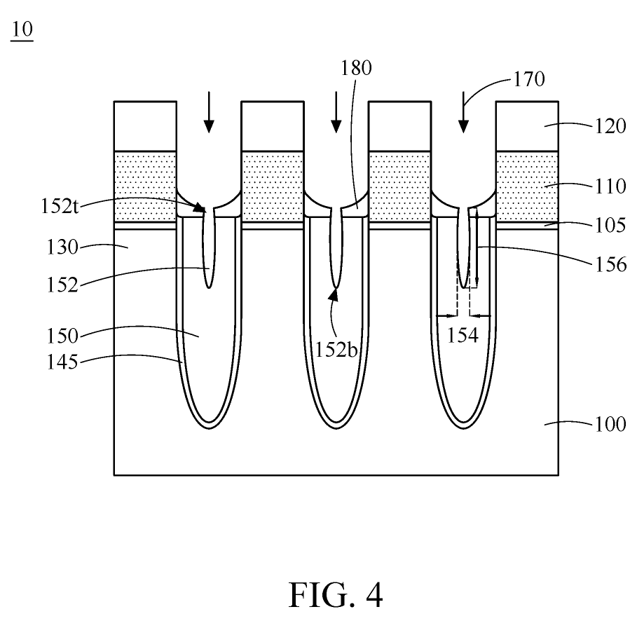

Referring next to FIG. 4, after performing the back-etching process 160 on the dielectric layer 150, an ion implantation process 170 is performed on the dielectric layer 150 to form an etch-stop layer 180 at an upper portion 150t of the dielectric layer 150. As shown in FIG. 4, the etch-stop layer 180 surrounds the top portion 152t of the first air gap 152, and the etch-stop layer 180 exposes the top portion 152t of the first air gap 152. In one embodiment, a bottom surface of the etch-stop layer 180 is higher than the top surface of the liner layer 105. In one embodiment, the ion implantation process 170 may utilize elements such as C, N, Si, or other suitable elements.

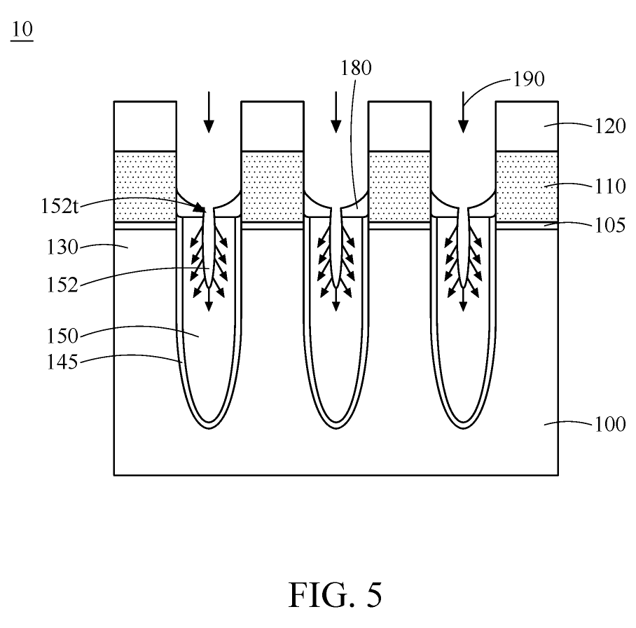

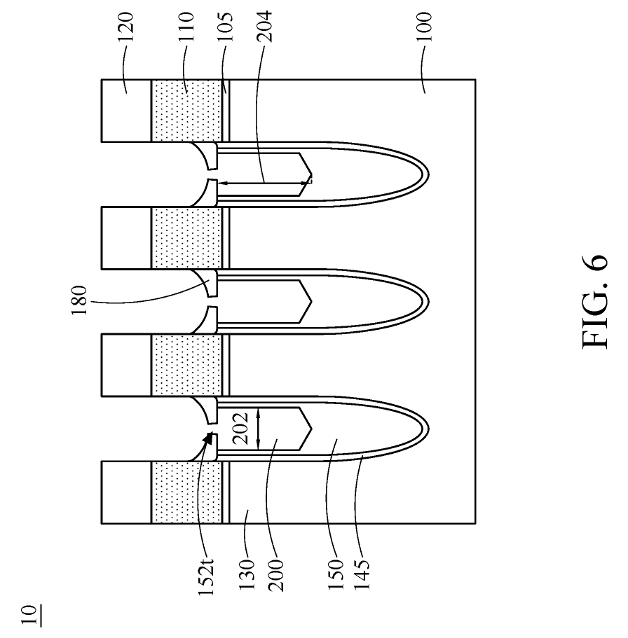

Referring to FIGS. 5 and 6, after the formation of the etch-stop layer 180, an etching process 190 is performed to remove a portion of the dielectric layer 150 exposed by the first air gap 152, thereby forming a second air gap 200. In one embodiment, the etching process 190 may include a wet etching process. In an example, an etchant used in the etching process 190 (e.g., a wet etching process) may flow into the first air gap 152 through the top portion 152t of the first air gap 152 to remove the portion of the dielectric layer 150. More specifically, the etching process 190 is an isotropic etching process, and the etchant flows into the first air gap 152 and etches the dielectric layer 150 located on the sidewalls and bottom of the first air gap 152. It should be noted that the etching process 190 does not completely etch the dielectric layer 150, that is, the second air gap 200 formed by the etching process 190 does not directly contact the active regions 130. In one embodiment, the etching process 190 may select an etchant that selectively etches only the material of the dielectric layer 150, such that the gate layer 110, the mask layer 120, and the etch-stop layer 180 are substantially not etched.

Still referring again to FIG. 6, a projected area of the second air gap 200 on the substrate 100 is greater than a projected area of the first air gap 152 on the substrate 100. In other words, since the second air gap 200 is formed by etching the first air gap 152, the second air gap 200 is greater than the first air gap 152. In one embodiment, the width 202 of the second air gap 200 is greater than the width 154 of the first air gap 152. In one embodiment, the width 202 of the second air gap 200 is less than the width 142 of each trench 140. In one embodiment, the depth 204 of the second air gap 200 is greater than the depth 156 of the first air gap 152. In one embodiment, the top surface of the second air gap 200 is higher than the top surface of the active regions 130.

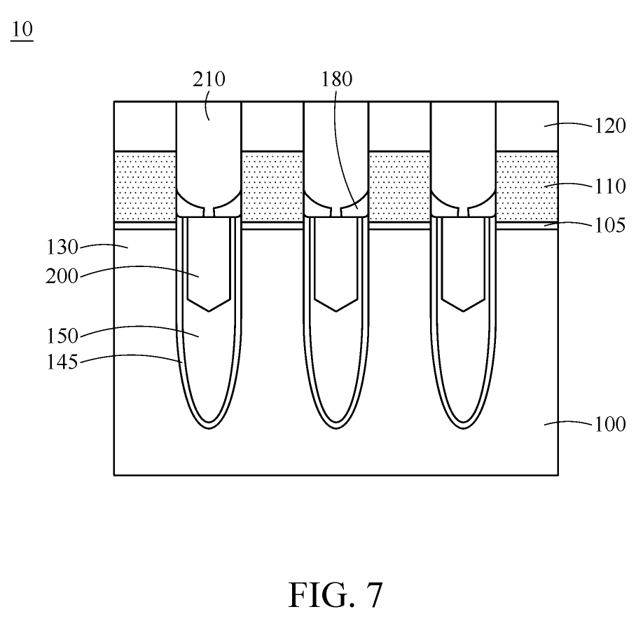

Referring next to FIG. 7, after the second air gap 200 is formed, a dielectric layer 210 may be formed on the dielectric layer 150 in the trench 140. In one embodiment, the dielectric layer 210 fills only the top portion 152t of the first air gap 152 and does not extend into the second air gap 200. In other words, the dielectric layer 210 is used to seal the top opening of the second air gap 200, i.e., the top portion 152t of the first air gap 152. It should be noted that, in the embodiments of the present disclosure, the etch-stop layer 180 has been modified by the ion implantation process and thus exhibits different etch selectivity with respect to the dielectric layer 150 during the etching process 190. As a result, the etch-stop layer 180 is substantially not etched, and the dimension of the exposed top portion 152t of the first air gap 152 is not enlarged, which facilitates the sealing of the top opening of the second air gap 200 by the dielectric layer 210. In one embodiment, the dielectric layer 210 is formed by using a deposition process with a relatively high deposition rate to prevent the dielectric material from entering and filling the second air gap 200. In one embodiment, after forming the dielectric layer 210, a chemical mechanical polishing (CMP) process may be performed on the dielectric layer 210 to expose the top surface of the mask layer 120. In one embodiment, the dielectric layer 210 may include an oxide or nitride, such as an oxide formed from tetraethylorthosilicate (TEOS), and may be formed by a chemical vapor deposition (CVD) process, a high aspect ratio process, another suitable deposition process, or a combination thereof.

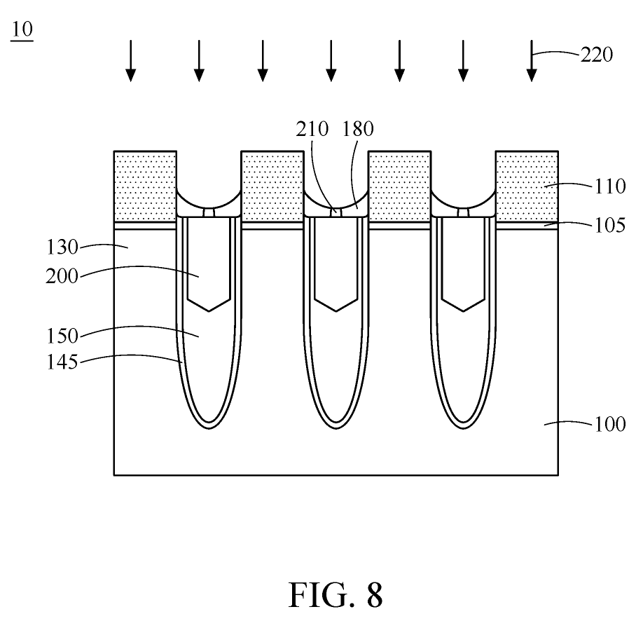

Referring to FIG. 8, after the dielectric layer 210 is formed (i.e., after sealing the top opening of the second air gap 200), a back-etching process 220 is performed on the dielectric layer 210 and the mask layer 120 to expose the top surface of the gate layer 110, with the dielectric layer 210 remaining at the top portion 152t of the first air gap 152. In one embodiment, after the back-etching process 220, the dielectric layer 150, the etch-stop layer 180, the second air gap 200, and the dielectric layer 210 collectively form an isolation structure, such as a shallow trench isolation (STI) structure. The isolation structure incorporating the air gaps described above may effectively reduce leakage issues that may occur between bit line structures due to device scaling. In one embodiment, the back-etching process 220 may include an anisotropic (or directional) etching process, such as a reactive ion (RIE) etching process, plasma etching, inductively coupled plasma (ICP) etching, or a combination thereof.

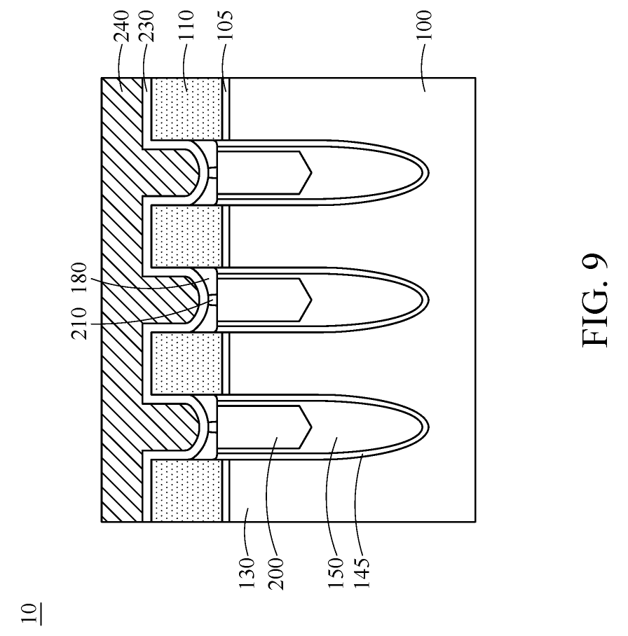

Referring to FIG. 9, after performing the back-etching process 220, an inter-gate dielectric layer 230 is conformally formed on the substrate 100 and the gate layer 110, and a gate layer 240 is subsequently formed on the inter-gate dielectric layer 230. More specifically, the inter-gate dielectric layer 230 conformally covers the sidewalls and the top surface of the gate layer 110, and the inter-gate dielectric layer 230 also conformally covers the top surfaces of the etch-stop layer 180 and the dielectric layer 210. In one embodiment, the inter-gate dielectric layer 230 is in direct contact with the top surface of the etch-stop layer 180, i.e., the dielectric layer 210 does not remain on the top of the etch-stop layer 180. The gate layer 240 may serve as a control gate of the semiconductor structure 10. In one embodiment, the second air gap 200 is separated from the inter-gate dielectric layer 230 by the etch-stop layer 180 and the dielectric layer 210. In one embodiment, the inter-gate dielectric layer 230 may be formed by a chemical vapor deposition (CVD) process, an atomic layer deposition (ALD) process, or a combination thereof. In one embodiment, the inter-gate dielectric layer 230 includes an oxide/nitride/oxide (ONO) layer (i.e., a composite layer), but the present disclosure is not limited to it, and the inter-gate dielectric layer 230 may alternatively be a single layer or a composite layer with a different number of sub-layers. In one embodiment, the gate layer 240 may include doped polysilicon, undoped polysilicon, metal, polycide, or a combination thereof, and may be formed by a chemical vapor deposition process or another suitable deposition process.

After the inter-gate dielectric layer 230 and the gate layer 240 are formed, the gate layer 110, the inter-gate dielectric layer 230, and the gate layer 240 collectively form a word line structure. After the gate layer 110, the inter-gate dielectric layer 230, and the gate layer 240 are formed, other components of the memory device may be subsequently formed, which are not further described herein.

In summary, the embodiments of the present disclosure provide a method for forming a semiconductor structure. First, trenches are formed in a substrate, and a dielectric layer having an air gap is formed within the trenches. A back-etching process is then performed to expose a top portion of the air gap. Subsequently, an ion implantation process is performed to modify the dielectric layer surrounding the top portion of the air gap, thereby forming an etch-stop layer at an upper portion of the dielectric layer. A further etching process is performed to remove the unmodified dielectric layer and enlarge the air gap. An additional dielectric layer is then formed to seal the air gap, resulting in an isolation structure that includes the air gap and may effectively isolate bit line structures. Thereby maintaining the yield and performance of the memory device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
providing a substrate;
sequentially forming a first gate layer and a mask layer over the substrate;
etching the substrate to form a plurality of active regions, wherein the active regions are isolated from each other by a plurality of trenches, and the trenches penetrate through the mask layer and the first gate layer;
forming a first dielectric layer in the trenches, wherein the first dielectric layer has a first air gap;
back-etching the first dielectric layer to expose a top portion of the first air gap;
performing an ion implantation process on the first dielectric layer to form an etch-stop layer at an upper portion of the first dielectric layer and surrounding the top portion of the first air gap;
removing a portion of the first dielectric layer exposed by the first air gap to form a second air gap;
forming a second dielectric layer on the first dielectric layer in the trenches;
back-etching the second dielectric layer and the mask layer to expose a top surface of the first gate layer, wherein the second dielectric layer remains at the top portion of the first air gap;
conformally forming an inter-gate dielectric layer on the substrate and the first gate layer; and
forming a second gate layer on the inter-gate dielectric layer.

2. The method as claimed in claim 1, wherein before forming the first gate layer, the method further comprises:
forming a liner layer on the substrate, wherein a bottom surface of the etch-stop layer is higher than a top surface of the liner layer.

3. The method as claimed in claim 1, wherein a projected area of the second air gap on the substrate is greater than a projected area of the first air gap on the substrate.

4. The method as claimed in claim 1, wherein the second air gap is separated from the inter-gate dielectric layer by the etch-stop layer and the second dielectric layer.

5. The method as claimed in claim 1, wherein removing the portion of the first dielectric layer exposed by the first air gap to form the second air gap further comprises:
using a wet etching process to etch the portion of the first dielectric layer exposed by the first air gap, wherein an etchant of the wet etching process flows into the first air gap through the top portion of the first air gap to remove the portion of the first dielectric layer.

6. The method as claimed in claim 1, wherein an element used in the ion implantation process comprises C, N, or Si.

7. The method as claimed in claim 1, wherein the second dielectric layer fills only the top portion of the first air gap.

8. The method as claimed in claim 1, wherein back-etching the first dielectric layer further comprises:
back-etching the first dielectric layer to position a top surface of the first dielectric layer below the top surface of the first gate layer, wherein the top surface of the first dielectric layer is higher than a top surface of the active regions.

9. The method as claimed in claim 1, wherein the inter-gate dielectric layer is in direct contact with a top surface of the etch-stop layer.

10. The method as claimed in claim 1, wherein materials of the first gate layer and the second gate layer comprise polysilicon.

11. The method as claimed in claim 1, wherein the inter-gate dielectric layer comprises an oxide/nitride/oxide layer.

12. The method as claimed in claim 1, wherein a top surface of the second air gap is higher than a top surface of the active regions.

13. The method as claimed in claim 1, wherein the first dielectric layer and the second dielectric layer comprise oxides or nitrides.

14. The method as claimed in claim 1, wherein the first dielectric layer, the etch-stop layer, the second air gap, and the second dielectric layer collectively form a trench isolation structure.

15. The method as claimed in claim 1, wherein a width of the second air gap is greater than a width of the first air gap.

16. The method as claimed in claim 1, wherein a width of the second air gap is less than a width of each of the trenches.

17. The method as claimed in claim 1, wherein a depth of the second air gap is greater than a depth of the first air gap.

18. The method as claimed in claim 1, wherein back-etching the first dielectric layer comprises performing an anisotropic etching process.

19. The method as claimed in claim 1, wherein forming the first dielectric layer in the trenches comprises using a deposition process with low step coverage to form the first air gap.

20. The method as claimed in claim 1, wherein after forming the second dielectric layer, a chemical mechanical polishing (CMP) process is performed to expose a top surface of the mask layer.
